(19) United States
(12) Patent Application Publication
(10) Pub. No.: US 2006/0156187 A1
(43) Pub. Date: Jul. 13, 2006

(54) Method and apparatus for multiple polynomial-based random number generation

(75) Inventors: Cheng-Wen Wu, Hsinchu (TW); Jen-Chieh Yeh, Taichung Hsien (TW); Hung-hsun Ou, Kaohsiung (TW)

Correspondence Address: NIXON & VANDERHYE, PC, 901 NORTH GLEBE ROAD, 11TH FLOOR, ARLINGTON, VA, 22203, US

(73) Assignee: NATIONAL TSING HUA UNIVERSITY, Hsinchu (TW)

(21) Appl. No.: 11/248,250

(22) Filed: Oct. 13, 2005

(30) Foreign Application Priority Data
Dec. 29, 2004 (TW) 093141121

(51) Int. Cl. H03M 13/00

(52) U.S. Cl. 714/759

(57) ABSTRACT

An apparatus for multiple polynomial-based random number generation includes an LUT device having a plurality of polynomials established therein, a signal selection unit coupled to the LUT device and operable so as to generate a select signal that is inputted to the LUT device to thereby select at least one of the polynomials established in the LUT device, and an LFSR device coupled to the LUT device and operable so as to perform LFSR operations based on the at least one of the polynomials selected from the LUT device. A method for multiple polynomial-based random number generation includes: a) establishing the polynomials in the LUT device, b) generating the select signal to select at least one of the polynomials, and c) enabling the LFSR device to perform the corresponding LFSR operations.

### CROSS-REFERENCE TO RELATED APPLICATION

This application claims priority of Taiwanese Application No. 093141121, filed on Dec. 29, 2004.

### BACKGROUND OF THE INVENTION

1. Field of the Invention

The present invention relates to a method and apparatus for random number generation. More particularly, the present invention relates a method and apparatus, in which there is utilized at least one linear feedback shift register in conjunction with multiple polynomials to generate random numbers.

2. Description of the Related Art

Computers can generate random numbers in two ways: (a) by utilizing a device interfaced to a computer that monitors a truly random natural event, such as radioactive decay of a radioactive material; and (b) by creating an algorithm that generates a string of pseudorandom numbers. The former approach is rare since it is impractical to equip computers with the instrumentation and materials needed for such a process. The latter approach, however, is common, and the pseudorandom numbers generated using such algorithms have a wide range of applications, including use in cryptography, bit-error-rate measurements, and wireless communication systems employing spread spectrum or CDMA techniques.

A linear feedback shift register (LFSR) is commonly used to generate pseudorandom bit sequences used for such applications. Referring to FIG. 1, an LFSR 6 may be represented by a single polynomial equation. An exemplary polynomial is provided by the following Equation 1:
x³¹+x⁶+x⁵+X³+x²⁺¹ (Equation 1)

After a bit sequence b₀˜b₃₁ fills an input pattern 61 of the LFSR 6, bits 31, 6, 5, 3, and 2 are tapped and output to an XOR gate 62 to thereby undergo an XOR logical operation. Tapping of the LFSR 6 is conducted on the basis of the exponents of Equation 1. The value obtained by the XOR logical operation performed by the XOR gate 62 is referred to as a seed 601, which is fed back to a least significant bit (LSB) b₀ of the input pattern 61. The timing of these operations is as follows: the selected bit values are collected before the LFSR 6 is clocked to undergo the XOR operation, then the seed 601 that is obtained is fed back into the LSB b₀ during the shift to thereby fill the LSB b₀ that is emptied as a result of the shift. A most significant bit (MSB) b₃₁ may be used as the output bit. Hence, a pseudorandom bit sequence is generated by repetition of the aforementioned operation. The pseudorandom bit sequence may be used to generate random numbers (i.e., pseudorandom numbers).

However, the LFSR 6 as described above is not without drawbacks. In particular, since only a single bit is output at a time, that is, for each clock cycle, the LFSR 6 is unsuitable for use in high-speed systems requiring multiple bit outputs. Further, with reference to FIG. 2, since the hardware logic circuit associated with the single polynomial LFSR cannot be altered, and the polynomial equation used therewith (and hence, the tap sequence) is also fixed, a random sequence 7 repeats in a fixed cycle. When applied to cryptography, for example, the random sequence 7 is susceptible to decryption.

### SUMMARY OF THE INVENTION

The object of this invention is to provide a method and apparatus for multiple polynomial-based random number generation, in which there is utilized at least one linear feedback shift register in conjunction with multiple polynomials to generate random numbers having superior random characteristics.

According to one aspect, the apparatus of this invention comprises: a look-up table (LUT) device having a plurality of polynomials established therein; a signal selection unit coupled to the LUT device and operable so as to generate a select signal that is inputted to the LUT device to thereby select at least one of the polynomials established in the LUT device; and a linear feedback shift register (LFSR) device coupled to the LUT device and operable so as to perform LFSR operations based on the at least one of the polynomials selected from the LUT device.

According to another aspect, the method of this invention comprises: a) establishing the plurality of polynomials in the LUT device; b) generating the select signal that is inputted to the LUT device to thereby select at least one of the polynomials established therein; and c) enabling the LFSR device to perform LFSR operations based on the at least one of the polynomials selected in step b).

### BRIEF DESCRIPTION OF THE DRAWINGS

Other features and advantages of the present invention will become apparent in the following detailed description of the preferred embodiment with reference to the accompanying drawings, of which:

FIG. 1 is a schematic view of a conventional 32-bit LFSR with a tap sequence of [31, 6, 5, 3, 2];

FIG. 2 is a schematic view illustrating a random sequence generated by the conventional LFSR that repeats in a fixed cycle;

FIG. 3 is a schematic circuit block diagram of an apparatus for random number generation according to a preferred embodiment of the present invention;

FIG. 4 is a schematic view of the preferred embodiment, illustrating interaction between a look-up table device, a linear feedback shift register device, and a logic gate unit; and

FIG. 5 is a flow chart of a method for multiple polynomial-based random number generation according to a preferred embodiment of the present invention.

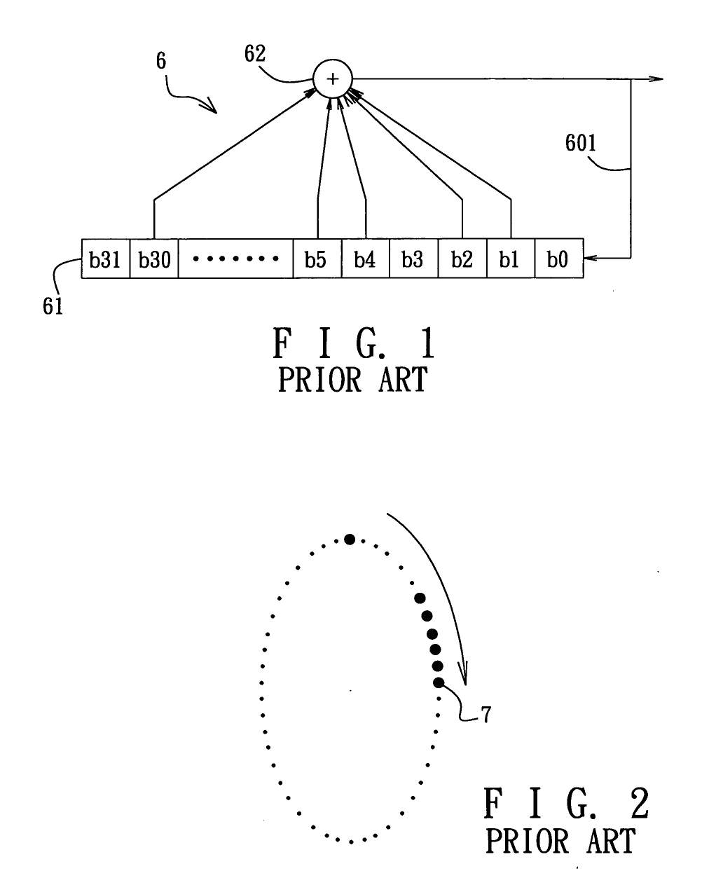

### DETAILED DESCRIPTION OF THE PREFERRED EMBODIMENT

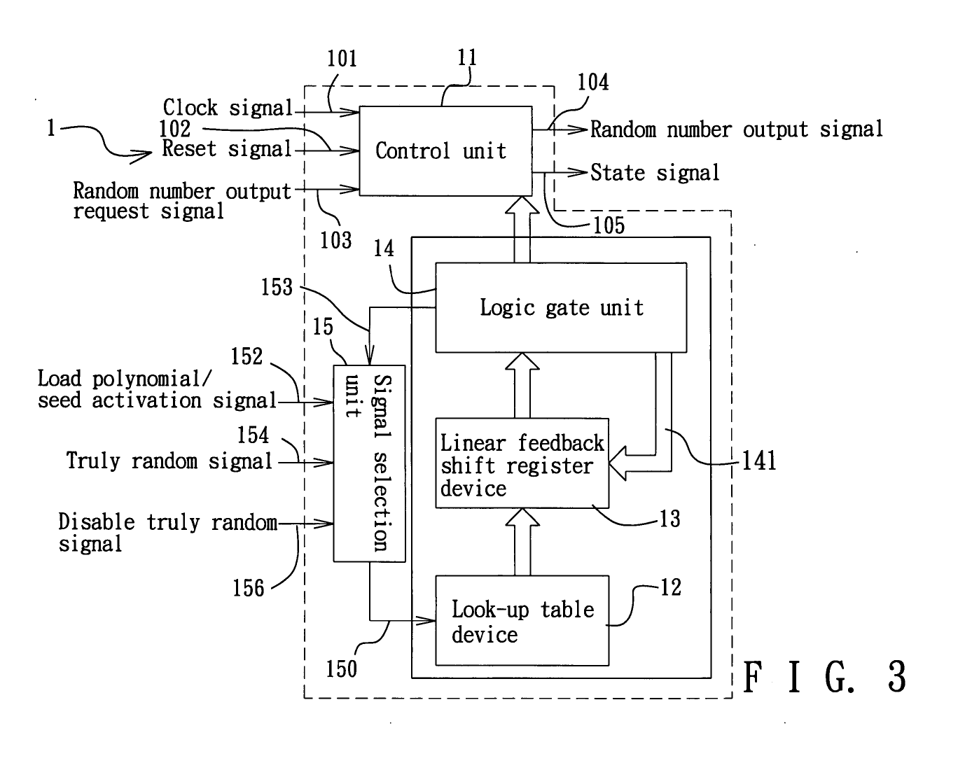

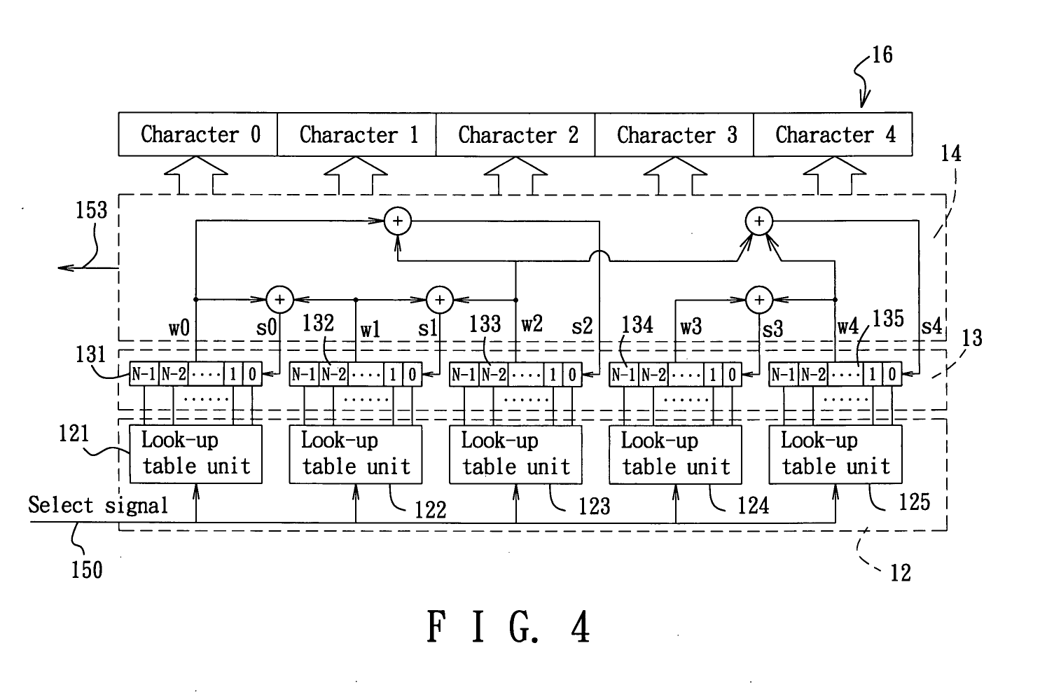

With reference to FIGS. 3 and 4, an apparatus 1 for generating random numbers according to a preferred embodiment of the present invention includes a control unit 11, a look-up table (LUT) device 12, a linear feedback shift register (LFSR) device 13, a logic gate unit 14, and a signal selection unit 15.

The control unit 11 receives a clock signal 101, a reset signal 102, and a random number output request signal 103. The clock signal 101 is used to synchronize the operations of the apparatus 1. The reset signal 102 is used to reset the apparatus 1 such that return to an initial state is performed. The random number output request signal 103 effects output of a random number output signal 104 from the control unit 11. Following output of the random number output signal 104, the control unit 11 outputs a state signal 105, indicating that the random number output signal 104 has been output.

The LUT device 12 includes a plurality of LUT units 121-125. A plurality of polynomials are established in each of the LUT units 121-125.

The LFSR device 13 includes a plurality of LFSR units 131-135, each of which performs a shift register function. The LFSR units 131-135 may be implemented using, for example, D flip-flops. The LSFR units 131-135 are associated respectively with the LUT units 121-125 in a manner to be described hereinafter.

The logic gate unit 14 is associated with the LFSR device 13 to perform logic operations on bit values of the LSFR units 131-135 of the LFSR device 13. The logic gate unit 14 also performs feedback to the LFSR device 13 of a seed sequence 141 (s0-s4 in FIG. 4) obtained through the logic operations.

The signal selection unit 15 is coupled to the LUT device 12 to output a select signal 150 thereto. The signal selection unit 15 receives a load polynomial/seed activation signal 152, a truly random source (TRS) signal 154, and a disable truly random source (DTRS) signal 156. The load polynomial/seed activation signal 152 effects selection of a polynomial from each of the LUT units 121-125 of the LUT device 12 according to the select signal 150, as well as input of an initial seed sequence to the LFSR device 13. When the user inputs the random number output request signal 103 to the apparatus 1, if it is the first operation when the seed sequence 141 still does not have a value, the load polynomial/seed activation signal 152 enables input of the initial seed sequence to the LFSR device 13.

Activation of the TRS signal 154 and the DTRS signal 156 may be controlled by the user. When the TRS signal 154 is asserted, this indicates selection to use an external truly random source, which is an arbiter signal that complies with the Advanced High-Performance Bus (AHB) standard of the Advanced Micro-controller Bus Architecture (AMBA) protocol in this embodiment. With the assertion of the TRS signal 154, the external truly random source generates the select signal 150 to select polynomials. The DTRS signal 156 disables functioning of the truly random source to select a polynomial. If the DTRS signal 156 is asserted, a random distribution start signal 153 generated by the logic gate unit 14 is input to the signal selection unit 15 for use as the select signal. Hence, a signal generated by the apparatus 1 itself is used to select polynomials. The processes involved when the DTRS signal 156 is asserted will be described in greater detail below.

As described above, the LUT device 12 includes a plurality of the LUT units 121-125. Each of the LUT units 121-125 contains a plurality of polynomials, an example of which is illustrated in Table 1 below.

TABLE 1
Look-up Table

| 121 | 122 | 123 | 124 | 125 |
|---|---|---|---|---|
| x⁷ + x³ + x² + x + 1 | x⁷ + x⁵ + x³ + x + 1 | x⁷ + x³ + 1 | x⁷ + x⁵ + x⁴ + x³ + 1 | x⁷ + x⁵ + x⁴ + |
| | | | | x³ + x² + x + 1 |
| x⁷ + x + 1 | x⁷ + x⁵ + x⁴ + x³ + x² + x + 1 | x⁷ + x⁶ + x⁵ + x⁴ + 1 | x⁷ + x⁶ + x⁵ + x⁴ + x³ + x² + x + 1 | x⁷ + x³ + 1 |
| x⁷ + x⁵ + x³ + x + 1 | x⁷ + x³ + 1 | x⁷ + x⁵ + x⁴ + x³ + 1 | x⁷ + x³ + x² + x + 1 | x⁷ + x³ + x² + x + 1 |
| x⁷ + x⁵ + x⁴ + | x⁷ + x⁶ + x⁵ + x⁴ + 1 | x⁷ + x⁶ + x⁵ + x⁴ + x³ + x² + x + 1 | x⁷ + x + 1 | x⁷ + x + 1 |
| x³ + x² + x + 1 | | | | |
| x⁷ + x³ + 1 | x⁷ + x⁵ + x⁴ + x³ + 1 | x⁷ + x³ + x² + x + 1 | x⁷ + x⁵ + x³ + x + 1 | x⁷ + x⁵ + x³ + x + 1 |
| x⁷ + x⁶ + x⁵ + x⁴ + 1 | x⁷ + x⁶ + x⁵ + | x⁷ + x + 1 | x⁷ + x⁵ + x⁴ + x³ + x² + x + 1 | x⁷ + x⁶ + x⁵ + x⁴ + 1 |
| | x⁴ + x³ + x² + x + 1 | | | |
| x⁷ + x⁵ + x⁴ + x³ + 1 | x⁷ + x³ + x² + x + 1 | x⁷ + x⁵ + x³ + x + 1 | x⁷ + x³ + 1 | x⁷ + x⁵ + x⁴ + x³ + 1 |
| x⁷ + x⁶ + x⁵ + | x⁷ + x + 1 | x⁷ + x⁵ + x⁴ + x³ + x² + x + 1 | x⁷ + x⁶ + x⁵ + x⁴ + 1 | x⁷ + x⁶ + x⁵ + |
| x⁴ + x³ + x² + x + 1 | | | | x⁴ + x³ + x² + 1 |

Preferably, the polynomials are 7-bit primitive polynomials, which have been determined to optimize the randomness of sequences of LFSRs. The random sequence generated by the present invention complies with the United States Federal Information Processing Standard 140-2 (FIPS140-2). Each of the LFSR units 131-135 has 7 bits (N=7) such that the total number of bits in the contents of the LFSR units 131-135 at any one time is 35 bits. From this total number of bits, k=3 bits are extracted for use as the random distribution start signal 153. Each of the LUT units 121-125 has 2^{k}=8 polynomials such that in a state where the DTRS signal 156 is asserted, the k=3 bit select signal 150 can select 8 different polynomials in each of the LUT units 121-125 as the input polynomial. Alternatively, three tapped values may be used as the select signal 150.

As described above, the logic gate unit 14 is associated with the LFSR device 13. The LFSR units 131-135 are tapped according to the polynomials selected respectively from the LUT units 121-125. The tapped values are then combined by the logic gate unit 14 to obtain the seed sequence 141 (or s0-s4). As an example, the logic gate unit 14 includes a plurality of XOR gates, and the tapped values of at least two of the LFSR units 131-135 are combined using the XOR gates to obtain a seed value for each of the LFSR units 131-135. Every cycle of the clock signal 101 results in a one-bit shift of the contents of each of the LFSR units 131-135 (a leftward shift is shown as an example in FIG. 4), and LSBs of the LFSR units 131-135 are filled with the obtained seed sequence 141 by the logic gate unit 14 performing feedback of the -seed sequence 141.

If it is determined that any one of the values of the seed sequence s0-s4 input to the LFSR units 131-135 is 0, predetermined seed values are used for input to the LFSR units 131-135. Thus, calculation of dead values by the LFSR device 13 as a result of “all 0” seed values is prevented. If it is determined that the seed sequence s0-s4 input to the LFSR units 131-135 have values (i.e., they are not all 0), a new seed sequence 141 calculated as described above is input to the LFSR device 13.

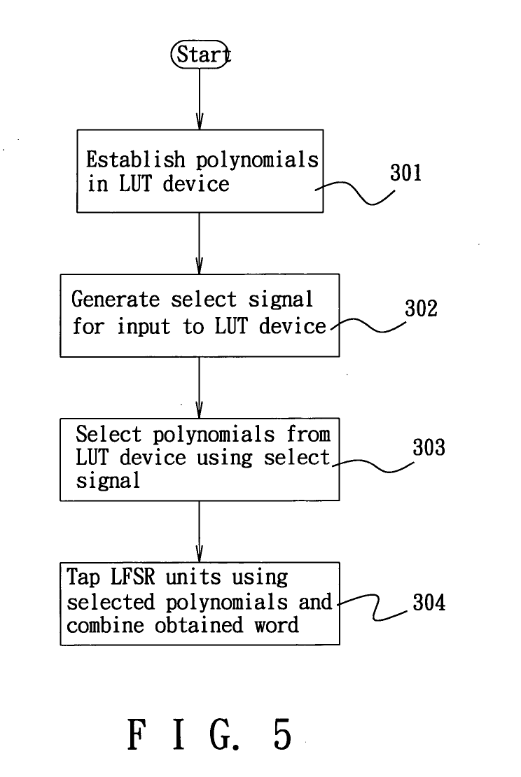

The preferred embodiment of a method for multiple polynomial-based random number generation according to this invention will now be described with reference to FIG. 5, in conjunction with FIGS. 3 and 4.

In step 301, polynomials are established in the LUT units 121-125 of the LUT device 12. As an example, the polynomials appearing in Table 1 are established in the LUT units 121-125.

Next, in step 302, the signal selection unit 15 facilitates generation of the select signal 150, and inputs the select signal 150 to the LUT device 12. If the TRS signal 154 has been asserted, a truly random source is used to generate the select signal 150. However, if the DTRS signal 156 has been asserted, three bits are extracted from the contents of the LFSR units 131-135 for use as the select signal 150, or alternatively, three bits from the tapped values of the LFSR units 131-135 are extracted for use as the select signal 150. In either case, the remaining bits (i.e., the remainder of the bits in the contents of the LFSR units 131-135 or the remainder of the tapped values) are used as an output result 16.

In step 303, the select signal 150 from the signal selection unit 15 is used to select polynomials in the LUT units 121-125 of the LUT device 12, the number of polynomials selected corresponding to the number of the LUT units 121-125. For example, if the random distribution start signal 153 used as the select signal 150 is 000, then selection is performed of the polynomials in the LUT units 121-125 that correspond to the first row of Table 1, namely, x7+x3+x2+x+1, x7+x5+x3+x+1, x7+x3+1, x7+x5+x4+x3+1, and x7+x5+x4+x3+x2+x+1.

Subsequently, in step 304, the LFSR units 131-135 are tapped according to the selected polynomials to thereby obtain a tapped word value for each of the LFSR units 131-135, after which the logic gate unit 14 combines the tapped word values in a predetermined manner. As an example, XOR operations are performed on character 0 through character 4 of the output result 16 of the LFSR units 131-135. If character 0 through character 4 are respectively designated w0, w1, w2, and w3, individual XOR operations are performed as follows: w0 ⊕ w1, w1⊕w2, w2⊕w0, w3⊕w4, and w4⊕w2, thereby obtaining the feedback seed sequence s0-s4. The feedback seed sequence s0-s4 is then fed back to the LFSR units 131-135, respectively, such that the LSBs of the LFSR units 131-135 are filled with these new binary values.

In the present invention described above, use of multiple polynomials can overcome the problem of repeating patterns in predetermined cycles. That is, with the use of the method and apparatus for random number generation of the present invention, a plurality of the LUT units 121-125 are used in conjunction with a plurality of the LFSR units 131-135 such that the polynomials selected are different for every clock cycle of the LFSR units 131-135, thereby resulting in a high degree of randomness of the bits fed back to the LFSR units 131-135. Hence, the bits used for generating random numbers also exhibit good random characteristics (i.e., non-repeating, good numeric distribution, and lack of predictability). It may also be possible to utilize the bit streams output as a result of the shifting of the LFSR units 131-135, in which case the randomness of the generated bit streams is also high.

Further, use of the plurality of the LSFR units 131-135 results in the output of multiple bits such that application to systems with faster bit stream requirements is possible.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A method for multiple polynomial-based random number generation comprising:
a) establishing a plurality of polynomials in a look-up table (LUT) device;
b) generating a select signal that is inputted to the LUT device to thereby select at least one of the polynomials established therein; and
c) enabling a linear feedback shift register (LFSR) device to perform LFSR operations based on said at least one of the polynomials selected in step b).

2. The method of claim 1, wherein the LFSR device includes a plurality of LFSR units, each of which performs respective LFSR operations based on said at least one of the polynomials selected in step b), said method further comprising:
d) generating a random number output from contents of the LFSR units after step c).

3. The method of claim 2, wherein the LUT device includes a plurality of LUT units,
in step a), each of the LUT units is established with a set of the polynomials,
in step b), the select signal is inputted to each of the LUT units to thereby enable selection of one of the polynomials from each of the LUT units, and
in step c), each of the LFSR units performs the respective LFSR operations based on said one of the polynomials selected in step b) from a respective one of the LUT units.

4. The method of claim 3, wherein the select signal is generated in step b) from the contents of the LFSR units.

5. The method of claim 1, wherein, in step b), the select signal is generated from a truly random source.

6. The method of claim 5, wherein the truly random source is an arbiter signal that complies with the Advanced High-Performance Bus (AHB) standard of the Advanced Micro-controller Bus Architecture (AMBA) protocol.

7. The method of claim 3, wherein step c) includes:
c1) tapping each of the LFSR units based on said one of the polynomials selected in step b) from the respective one of the LUT units to thereby obtain a tapped word value for each of the LFSR units.

8. The method of claim 7, wherein step c) further includes:
c2) combining the tapped word values of the LFSR units in a predetermined manner to obtain a set of feedback seed values that correspond to the LFSR units, respectively; and
c3) feeding back the feedback seed values to the LFSR units, respectively.

9. An apparatus for multiple polynomial-based random number generation, comprising:
a look-up table (LUT) device having a plurality of polynomials established therein;
a signal selection unit coupled to said LUT device and operable so as to generate a select signal that is inputted to said LUT device to thereby select at least one of the polynomials established in said LUT device; and
a linear feedback shift register (LFSR) device coupled to said LUT device and operable so as to perform LFSR operations based on said at least one of the polynomials selected from said LUT device.

10. The apparatus of claim 9, wherein said LFSR device includes a plurality of LFSR units, each of which performs respective LFSR operations based on said at least one of the polynomials selected from said LUT device.

11. The apparatus of claim 10, wherein a random number output is obtained from contents of said LFSR units.

12. The apparatus of claim 11, wherein the random number output is a random sequence that complies with the United States Federal Information Processing Standard 140-2 (FIPS140-2).

13. The apparatus of claim 9, wherein said LUT device includes a plurality of LUT units, each of which is established with a set of the polynomials,
wherein the select signal is inputted to each of said LUT units to thereby enable selection of one of the polynomials from each of said LUT units, and
wherein each of said LFSR units performs the respective LFSR operations based on said one of the polynomials selected from a respective one of said LUT units.

14. The apparatus of claim 13, wherein said signal selection unit is coupled to said LFSR units and generates the select signal from contents of said LFSR units.

15. The apparatus of claim 9, wherein said signal selection unit is adapted to be coupled to a truly random source so as to generate the select signal.

16. The apparatus of claim 13, wherein each of said LFSR units is tapped based on said one of the polynomials selected from the respective one of said LUT units to thereby obtain an initial seed value for each of said LFSR units.

17. The apparatus of claim 16, further comprising a logic gate unit coupled to said LFSR device for combining the tapped word values of said LFSR units in a predetermined manner to obtain a set of feedback seed values that correspond to said LFSR units, respectively;
wherein the feedback seed values are fed back to said LFSR units, respectively.

18. The apparatus of claim 13, wherein the number of the polynomials established in each of the LUT units is 2^{k}, and the select signal includes k bits.

19. The apparatus of claim 9, wherein each of the polynomials is a 7-bit primitive polynomial.
